(19) United States
(12) Patent Application Publication
(10) Pub. No.: US 2007/0038904 A1
(43) Pub. Date: Feb. 15, 2007

(54) Information storage medium, information recording/playback apparatus, and method of recording and playing back information

(76) Inventor: Minako Morio, Kawasaki-Shi (JP)

Correspondence Address: KNOBBE MARTENS OLSON & BEAR LLP, 2040 MAIN STREET, FOURTEENTH FLOOR, IRVINE, CA, 92614, US

(21) Appl. No.: 11/493,956

(22) Filed: Jul. 27, 2006

(30) Foreign Application Priority Data
Jul. 28, 2005 (JP) 2005-219610

(51) Int. Cl. G11C 29/00

(52) U.S. Cl. 714/710

(57) ABSTRACT

A rewritable information storage medium includes a user area for storing user data, a defect management area for storing defect management information relating to a defective area in the user area, and a spare area serving as a replacement area for storing the user data that was unable to be stored in the defective area. The rewritable information storage medium stores the defect management information in an area other than the defect management area in addition to the defect management area.

### BACKGROUND OF THE INVENTION

1. Field of the Invention

The present invention relates to an information storage medium, an information recording/playback apparatus, and a method of recording and playing back information, in particular, to a rewritable information storage medium including an optical disk, an information recording/playback apparatus for recording information onto and playing back information from the information storage medium, and a method of recording and playing back the information.

2. Description of the Related Art

Known information storage media which can have information rewritably recorded thereon (e.g., optical disks) include a mechanism to compensate for a “defective recording area” thereon. An area used for managing the defect recording area is referred to as a “defect management area (DMA)”.

As the number of defective recording areas increases, the DMA is overwritten. In general, the characteristics of the information storage medium deteriorate due to overwriting. Accordingly, the maximum number of allowed overwrites is restricted. If a medium has a relatively small maximum number of allowed overwrites (such as a high-density optical disk using a blue laser), overwriting for updating the DMA becomes problematic. That is, as the number of overwritings increases, the DMA itself, which records the defect information, may become defective.

Accordingly, JP 2004-288285 A, for example, describes a technology in which the defect management information is stored in a plurality of physically separated areas so that redundancy is added to the defect management information. Thus, even when one DMA becomes defective, the defect management information stored in another DMA can compensate for the defective defect management information. Furthermore, technology has been proposed in which, when the number of DMA updates exceeds a predetermined maximum number of allowed overwrites, the defect management information stored in that DMA is relocated to another DMA.

The information storage medium (e.g., an optical disk) described in JP 2004-288285 A includes a spare area in addition to a user area that generally stores ordinary data (user data). If part of the user area becomes defective, the user area is expanded using the spare area so as to maintain the user area. Alternatively, the user data to be stored in that defective part of the user area is relocated to the spare area. The expansion of the user data area or the replacement of the user data area is made on a predetermined data unit basis (This data unit is referred to as an “ECC block”).

For example, when user data in a replacement area is played back (is read out), defect management information that associates address information about the defective original area with address information about the replacement area is required. The DMA stores such defect management information. The DMA is provided in an area different from the user area and the spare area.

Known DVD-RAMs and the next generation high-density optical disks (such as HD DVD-RWs) include four DMAs: two DMAs in the innermost peripheral area and two DMAs in the outermost peripheral area of the optical disks. The same defect management information is stored in these four DMAs. Consequently, even when a dust is deposited onto one of the DMAs or one of the DMAs is damaged, the defect management information in the other DMAs is normal. Thus, the reliability of the defect management information can be increased.

Additionally, for the HD DVD-RWs, which have a smaller maximum number of allowed overwrites than the DVD-RAMs, each of the four DMAs is separated into a plurality of sub-DMAs (e.g., 100 sub-DMAs). When the number of overwrites to the DMA is about to exceed the maximum number of allowed overwrites or the error rate of data exceeds a predetermined range, the defect management information in that DMA is relocated to another DMA. By sequentially repeating this operation, up to 100 updates can be allowed.

Thus, a variety of techniques have been proposed in order to increase the reliability of the defect management information stored in the DMA. However, the possibility of read errors occurring in all the defect management information still exists.

If all the defect management information stored in the DMAs are unreadable, the stored user data cannot be played back. Therefore, a user suffers a great loss.

### SUMMARY OF THE INVENTION

Accordingly, it is an object of the present invention to provide an information storage medium, an information recording/playback apparatus, and a method of recording and playing back information that are capable of correctly reading user data even when all the defect management information stored in the DMAs are unreadable.

According to an embodiment of the present invention, a rewritable information storage medium includes a user area for storing user data, a defect management area for storing defect management information relating to a defective area in the user area, and a spare area serving as a replacement area for storing the user data that was unable to be stored in the defective area. The defect management information is stored in an area other than the defect management area in addition to the defect management area.

According to another embodiment of the present invention, an information recording/playback apparatus for recording data on and playing back data from a rewritable information storage medium includes first storing means for storing user data in a user area of the information storage medium, second storing means for storing defect management information relating to a defective area of the user area in a defect management area of the information storage medium, third storing means for relocating and storing user data that was unable to be stored in the defective area in a spare area of the information storage medium, and fourth storing means for storing the defect management information in an area other than the defect management area in addition to the defect management area.

According to still another embodiment of the present invention, an information recording/playback method for recording data on and playing back data from a rewritable information storage medium includes the steps of storing user data in a user area of the information storage medium, storing defect management information relating to a defective area of the user area in a defect management area of the information storage medium, relocating and storing user data that was unable to be stored in the defective area in a spare area of the information storage medium, and storing the defect management information in an area other than the defect management area in addition to the defect management area.

Thus, according to the present invention, the information storage medium, the information recording/playback apparatus, and the method of recording and playing back information can correctly read out user data even when all the defect management information stored in the DMAs are unreadable.

### BRIEF DESCRIPTION OF THE DRAWINGS

FIG. 1A is a schematic illustration of the physical data layout of a rewritable information storage medium 1 (e.g., a next-generation DVD, an HD DVD-RW, and an HD DVD-RAM);

FIG. 1B illustrates the data structure of the information storage medium 1;

FIG. 2 illustrates the data structure of a DMA 1 and a DMA 2 recorded in a lead-in area and a DMA 3 and a DMA 4 recorded in a lead-out area;

FIG. 3A illustrates an exemplary data structure of a DDS/PDL;

FIG. 3B illustrates an exemplary data structure of an SDL;

FIG. 4 illustrates an exemplary byte allocation of the DDS;

FIG. 5 illustrates an exemplary byte allocation of the PDL;

FIG. 6 illustrates the bit allocation of a PDL entry;

FIG. 7 illustrates an exemplary byte allocation of the SDL;

FIG. 8 illustrates the bit allocation of a SDL entry;

FIG. 9 illustrates a method for relocating the data segment of the defective sector registered in the PDL;

FIG. 10 illustrates a method for relocating a data segment in a defective sector registered in the SDL;

FIG. 11 illustrates the replacement of the DMAs;

FIGS. 12A and 12B illustrate the data structure of user data recorded in an HD DVD-RW;

FIG. 13 is a flow chart illustrating the operation of an information recording/playback apparatus according to an embodiment of the present invention when a backup DMA is stored in a first mode;

FIG. 14 is a flow chart illustrating the operation of the information recording/playback apparatus according to the embodiment of the present invention when the backup DMA is stored in a second mode; and

FIG. 15 illustrates an exemplary system configuration of the information recording/playback apparatus according to the embodiment of the present invention.

### DESCRIPTION OF THE PREFERRED EMBODIMENTS

An information storage medium, an information recording/playback apparatus, and a method of recording and playing back information according to an embodiment of the present invention are now herein described with reference to the accompanying drawings.

(1) Data Structure of Information Storage Medium

An information storage medium 1 according to an embodiment of the present invention and the data structure of the information storage medium 1 on which an information recording/playback apparatus 100 records information and from which an information recording/playback apparatus 100 plays back information are described next.

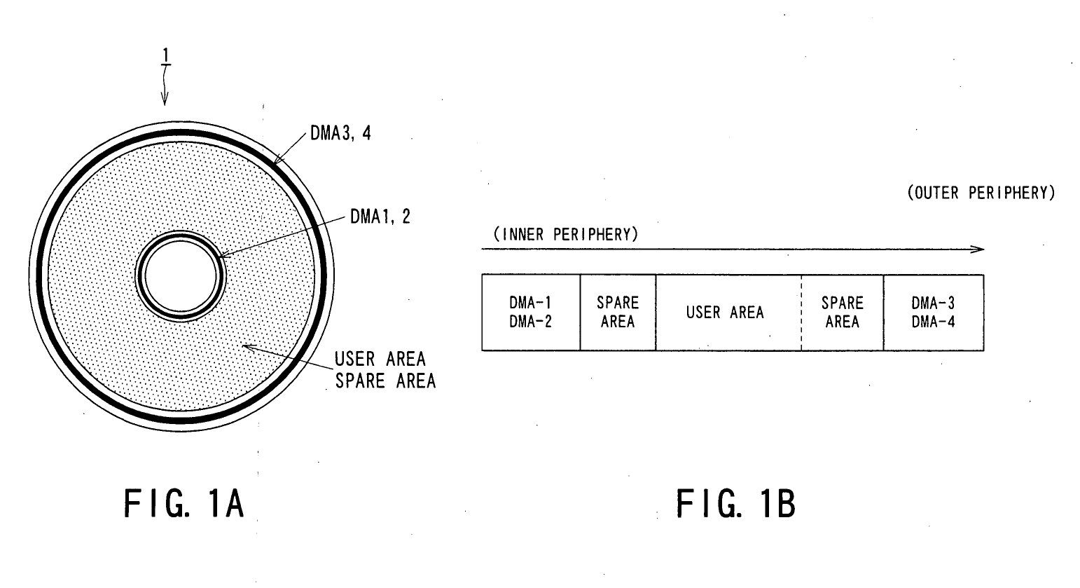

FIG. 1A is a schematic illustration of a physical data layout of the rewritable information storage medium 1 (e.g., a next-generation DVD: an HD DVD-RW or an HD DVD-RAM).

The recording surface of the information storage medium 1 is mostly occupied by a user area. Part of the user area is used as a spare area. The user area stores user data, such as video and audio data and data of a variety of information. If data is not correctly written to the user area, the spare area is used as a replacement area for the area (defective area) into which the data has not been correctly written.

A ring-shaped region called a “data lead-out area” is provided in an outer periphery of the user area, which includes the spare area. The data lead-out area includes a sub-area called a “defect management area (DMA)”.

Additionally, a ring-shaped region called a “data lead-in area” is provided in an inner periphery of the user area. The data lead-in area also includes a DMA.

FIG. 1B illustrates the data structure of the information storage medium 1. As described above, the information storage medium 1 includes the data lead-in area in the inner periphery thereof and the data lead-out area in the outer periphery thereof. In the data lead-in area, a DMA 1 and a DMA 2 are provided. In the data lead-out area, a DMA 3 and a DMA 4 are provided.

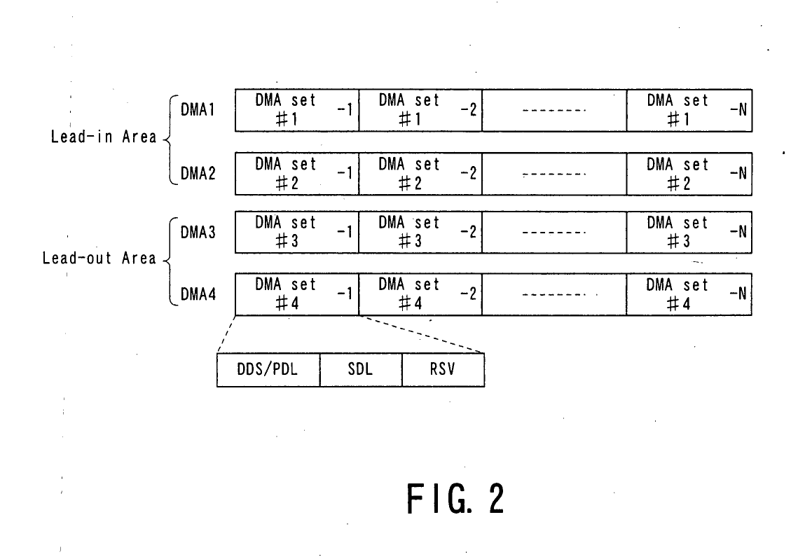

FIG. 2 illustrates the data structure of the DMA 1 and DMA 2 recorded in the lead-in area and the DMA 3 and DMA 4 recorded in the lead-out area.

The DMA 1 includes DMA subsets #1-1 to #1-N. The N subsets of DMA #1 form one set. Similarly, the DMA 2, the DMA 3, and the DMA 4 include DMA subsets #2-1 to #2-N, DMA subsets #3-1 to #3-N, and DMA subsets #4-1 to #4-N, respectively. Thus, the N subsets of DMA #2 form one set. The N subsets of DMA #3 form one set, and the N subsets of DMA #4 form one set.

For an HD DVD-RW, which is a next-generation DVD, in general, N is set to 100. That is, each of the DMAs 1 to 4 is a set of 100 subsets of the DMA.

The defect management information stored in the DMA includes address information about a user area updated by expanding the user area using the spare area when user data is not correctly written to the data area due to some defect, address information about the defective data area when data is not correctly written, and information for associating the address (old address) of the unwritable area (defective area) with an address (new address) of a spare area used for an alternative data writing area. Even when user data is not recorded in the data area due to some defect of the data area, the user data can be reliably played back by referencing the defect management information in the DMA and reading out the address information about the expanded user area, the defect information, and the user data recorded in the alternative spare area during playback.

The same defect management information is recorded in the DMAs 1 to 4. By recording the same defect management information in the four physically separated areas, even when one of the DMAs becomes unreadable due to a defect, such as a scratch or fingerprint on the disk, the defect management information can be read from one of the other DMAs. Thus, fault tolerance can be increased.

If a new defect is found in the data area, information about the defect is written to the DMAs. Thus, the defect management information in the DMAs is updated (overwritten) every time a defect is found. The rewritable information storage medium 1 gradually deteriorates with the overwriting. That is, the DMA itself deteriorates. Accordingly, for example, the HD DVD-RWs include a plurality of changeable DMAs (more specifically, 100 DMA subsets). If the number of overwritings to one DMA exceeds a predetermined number or if a possibility of unreadable data being created increases (i.e., the symbol error rate exceeds a predetermined value), the defect management information is copied to the next DMA and the currently used DMA is changed to the next DMA. By sequentially repeating this operation, the change can be made up to 100 times.

Each subset of the DMA includes defect management information called a DDS/PDL and defect management information called a SDL. In addition, each subset of the DMA includes a reserved area (RSV).

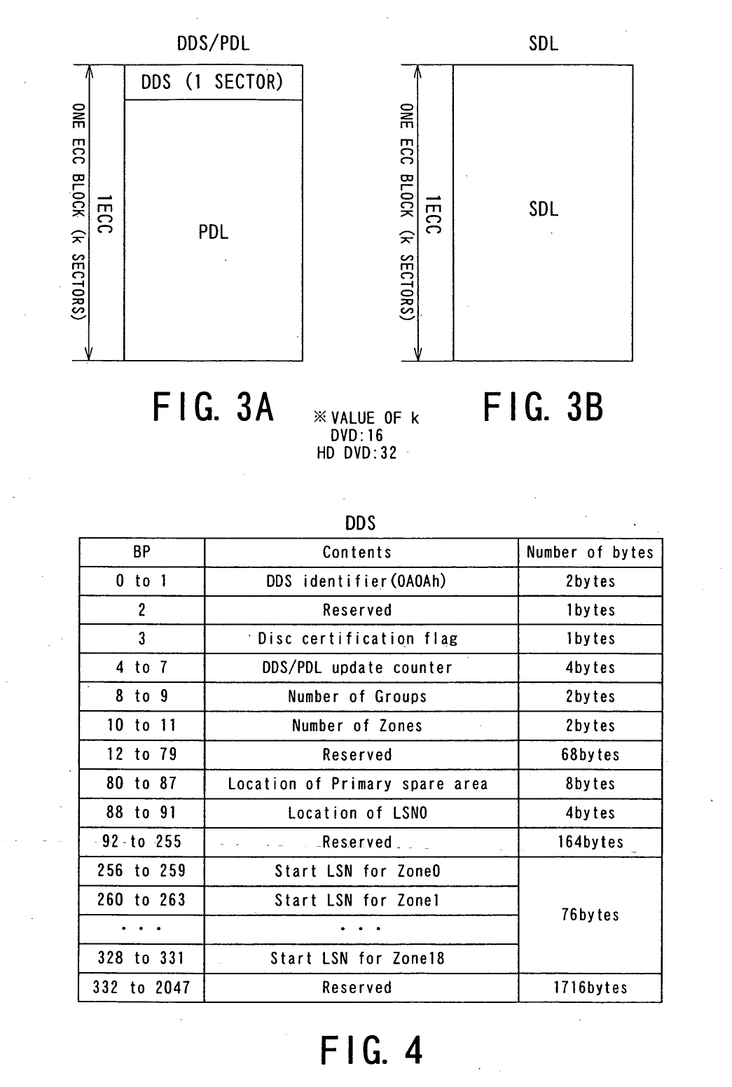

FIG. 3A illustrates an exemplary data structure of the DDS/PDL, while FIG. 3B illustrates an exemplary data structure of the SDL.

Each of the DDS/PDL, SDL, and the reserved area (RSV) of the DMA is composed of data blocks called ECC blocks. A predetermined error correction code (ECC) is allocated to each ECC block. Within a predetermined number of errors, a symbol error can be corrected on an ECC block basis.

The ECC block is divided into units of data called sectors. Depending on the type of the information storage medium 1, the information storage medium 1 has an ECC block including 16 sectors or 32 sectors. For example, for known DVDs, one ECC block includes 16 sectors. In contrast, for next-generation DVDs (e.g., HD DVD-RWs), one ECC block includes 32 sectors.

The data size of a sector is 2 Kbytes regardless of the type of the information storage medium 1. Therefore, for known DVDs, the data size of the ECC block is 32 Kbytes (16 sectors×2 Kbytes). For HD DVD-RWs, the data size of the ECC block is 64 Kbytes (32 sectors×2 Kbytes).

The DDS/PDL block is divided into a region called a DDS (disc definition structure) and a region called a PDL (primary defect list).

The data size of the DDS is 2 Kbytes (one sector). FIG. 4 illustrates an exemplary byte allocation of the DDS. In the DDS, information about the definition and structure of the disk (e.g., the “DDS identifier”, the “number of groups”, and the “number of zones”) and information about the physical address of the write start position (“location of LSN0”) are recorded.

The PDL is a primary defect list for storing information about initial defects. The data size of the PDL is the size determined by subtracting the data size of the DDS from the size of the DDS/PDL block (ECC block). For the known DVDs, the size of the PDL is 30 Kbytes (15 sectors×2 Kbytes). For HD DVD-RWs, the size of the PDL is 62 Kbytes (31 sectors×2 Kbytes).

In the PDL, defect management information about, for example, defects made at time of manufacturing, defects found at a certification time of the first formatting, and defects moved from the SDL at a formatting time after the disk has started to be used are recorded.

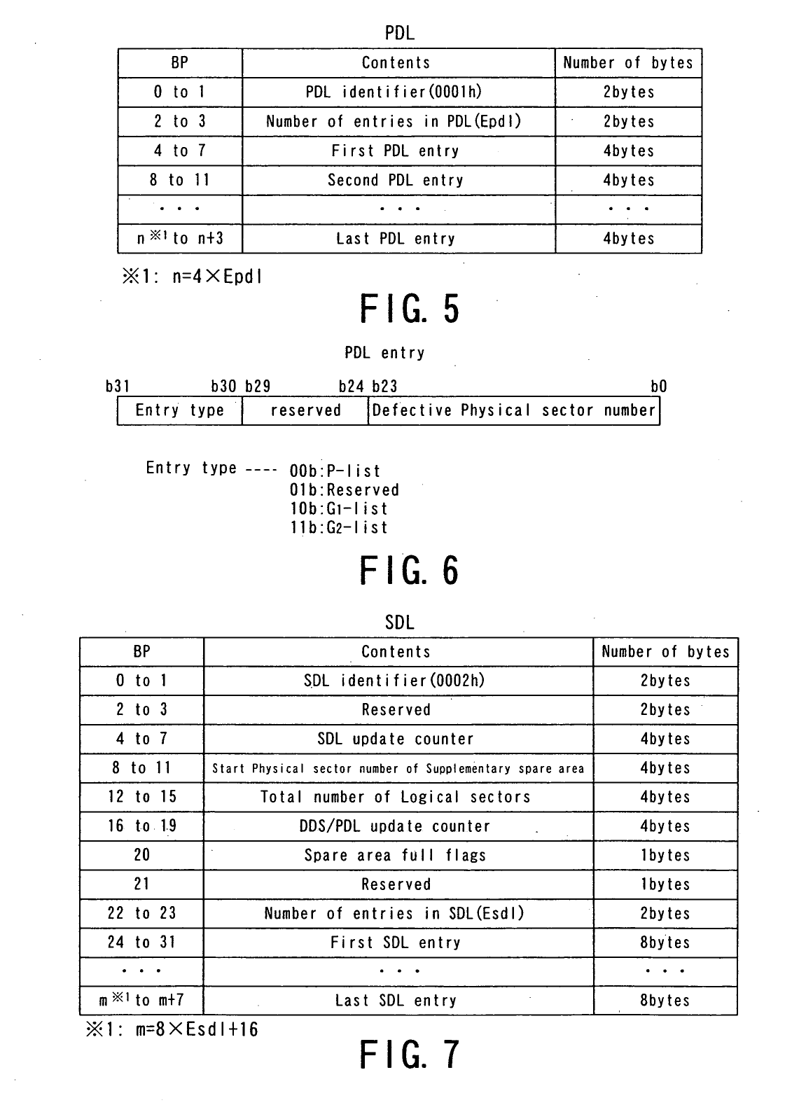

FIG. 5 illustrates an exemplary byte allocation of the PDL. The PDL contains the following fields from the head to the tail thereof: a 2-byte identifier (“PDL identifier”); a 2-byte field for storing the number of PDL entries in the DDS/PDL block (“Number of entries in the PDL”); and a zone for sequentially storing PDL entries, each being 4 bytes.

Each PDL entry includes information for managing one initial defect. The number of the PDL entries depends on the number of initial defects. As the number of initial defects increases, the number of the PDL entries increases.

FIG. 6 illustrates the bit allocation of the 4-byte PDL entry. The PDL entry stores a 2-bit entry type, a 6-bit reserved area, and a 24-bit defective physical sector number.

The entry type is used for identifying whether the entry contains defective sector information recorded by the manufacturer of the information storage medium 1 (a P-list), defective sector information found in a disk certification step (a G1-list), or defective sector information moved from the SDL after formatting (a G2-list).

The defective physical sector number is the information containing the physical sector number of a defective physical segment block. By using the defective physical sector number, the address of a user area where a defect occurred can be identified.

The PDL stores defective management information relating to a primary defect (initial defect), whereas the SDL stores defective management information relating to a secondary defect. That is, the SDL stores defective management information relating to a defect found at a recording time of normal user data (the secondary defect).

FIG. 7 illustrates an exemplary byte allocation of the SDL. The SDL contains the following fields from the head to the tail thereof: information fields used for managing the SDL itself, such as an identifier (“SDL identifier”); a 2-byte field starting from byte 22 for storing the number of SDL entries in the SDL block (“Number of entries in the SDL”); and a zone for sequentially storing SDL entries, each being 8 bytes.

Each SDL entry includes information for managing one secondary defect. The number of SDL entries depends on the number of secondary defects. As the number of secondary defects increases in accordance with the use of the information storage medium 1, the number of SDL entries increases.

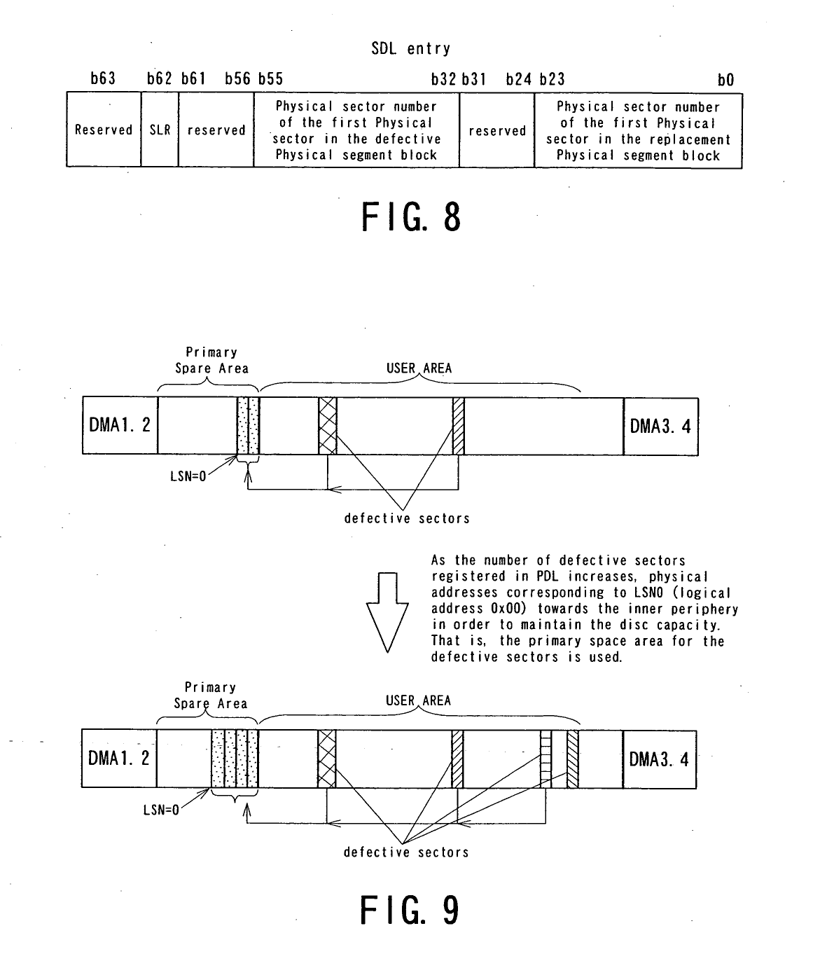

FIG. 8 illustrates an exemplary bit allocation of the SDL entry (8 bytes). The SDL entry contains a flag “SLR” that indicates whether data relocation has occurred or not due to a secondary defect, address information before the relocation occurred (a relocated source address), and address information after the relocation occurred (a replacement destination address).

The address information before relocation is stored in a 24-bit field designated as “Physical sector number of the first Physical sector in the defective Physical segment block” in FIG. 8. Also, the address information after the relocation is stored in a 24-bit field designated as “Physical sector number of the first Physical sector in the replacement Physical segment block” in FIG. 8.

If a defect occurs in the user area and the user data cannot be correctly written, the user data to be written to the defective area is written to a spare area.

FIG. 9 illustrates a method for relocating the data segment of the defective sector registered in the PDL. As noted above, there are three entry types of the PDL: defective sector information recorded by the manufacturer of the information storage medium 1 (the P-list), defective sector information found in a disk certification stage (the G1-list), and defective sector information moved (or copied) from the SDL after formatting (the G2-list). All the information is recorded when the use of the information storage medium 1 is started or when the information storage medium 1 is formatted. That is, the information is not the information about a defect found during the use of the information storage medium 1 by a user. An area for storing the capacity of the blocks identified as blocks including a defective sector at a starting time of the usage or at a formatting time is used from the primary spare area to maintain the constant user area for recording.

The primary spare area is located at a position adjacent to the inner periphery of the user area. The primary spare area is used from the position adjacent to the user area towards the center of the information storage medium 1. The head of the data stored in the primary spare area is recorded at the head of the data area, namely, at the logical address “0”. The data position (physical address) of the disk corresponding to the starting point of the data area is recorded in the field “Location of LSN0” of the DDS (see the byte allocation of DDS shown in FIG. 4).

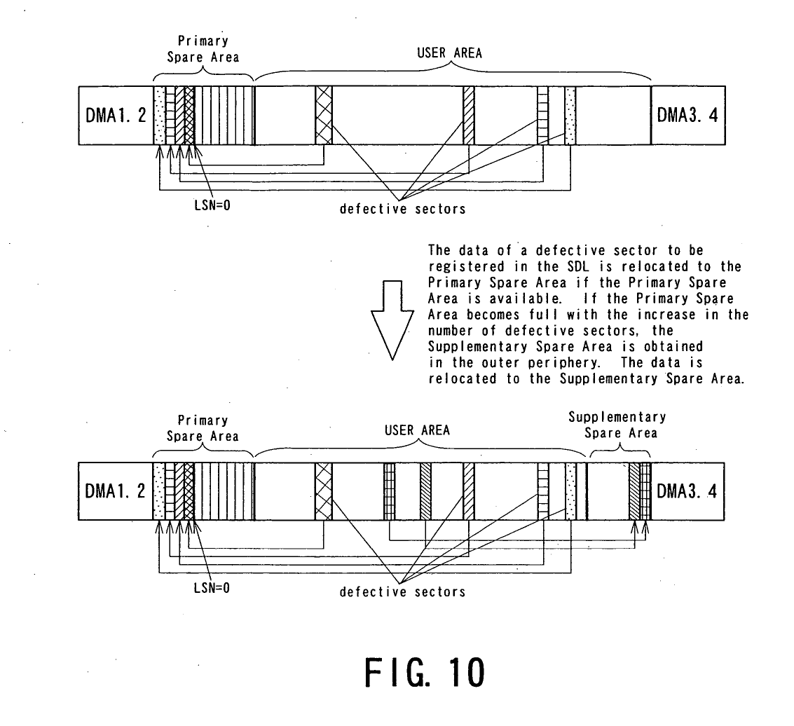

FIG. 10 illustrates a method for relocating a data segment in a defective sector registered in the SDL. In an entry of the SDL, an address of the data segment to be relocated and an address of the replacement data segment relating to a defect detected during the use of the information storage medium 1 are recorded. If an information recording/playback apparatus 100 reads data from or writes data to an address on the information storage medium 1 and the address indicates a data segment including a defective address (the address to be relocated) recorded in the SDL, the information recording/playback apparatus 100 reads data from or writes data to the data segment at the replacement address recorded in the SDL instead of using the defective address. The replacement address is an address in the spare area. If a free area exists in the primary spare area, the primary spare area is used for the replacement area. If a free area is not available in the primary spare area, a supplementary spare area is obtained in the outer periphery of the information storage medium 1 adjacent to the user area so that this area is used for the replacement area.

As described above, the defect management information recorded in the DMA (DDS/PDL and SDL) associates the address of an unwritable area (a defective area) (i.e., the address of an area to be relocated) with the address of a spare area to which unwritable data is written (i.e., the replacement address) when user data is not correctly written due to a defect of the data area. Accordingly, even when the user data is not correctly recorded in the data area due to a defect of the data area, the user data can be played back by referencing the defect management information in the DMA and reading the user data relocated into the spare area.

The same defect management information is recorded in the DMAs 1 to 4. By recording the same defect management information in the four areas which are physically separated from each other, even when one of the DMAs becomes unreadable due to a defect, such as a scratch or fingerprint on the disk, the defect management information can be read from one of the other DMAs. Thus, fault tolerance can be increased.

If a new defect is found in the data area, information about the defect is written to the DMAs. Thus, the defect management information in the DMAs is updated (overwritten) every time a defect is found. The rewritable information storage medium 1 gradually deteriorates with the overwriting. That is, the DMA itself deteriorates. Accordingly, for example, the HD DVD-RWs include a plurality of changeable DMAs (more specifically, 100 DMAs). If the number of overwritings to one DMA exceeds a predetermined number or if a possibility of unreadable data being created increases (i.e., the symbol error rate exceeds a predetermined value), the defect management information is copied to the next DMA and the currently used DMA is changed to the next DMA. By sequentially repeating this operation, the change can be made up to 100 times.

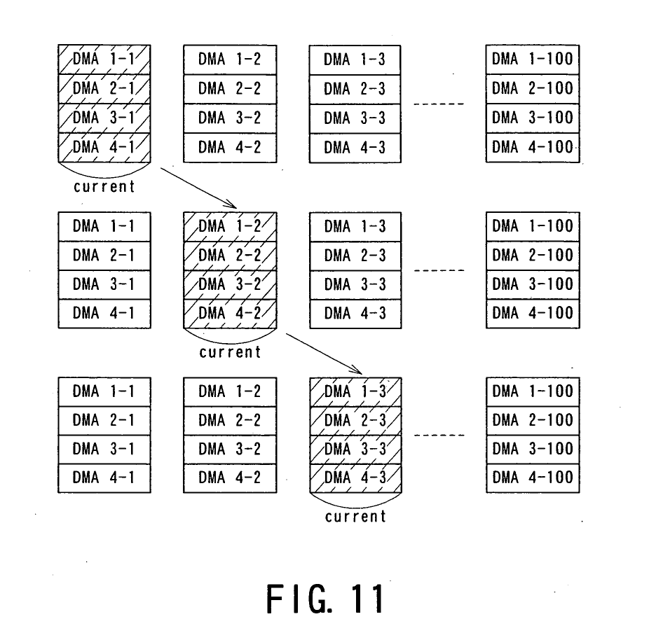

FIG. 11 illustrates the replacement process of the DMAs.

When using the DMA, the head of each set (i.e., DMA 1-1, DMA 2-1, DMA 3-1, or DMA 4-1) is used first. If one of the heads of the DMAs becomes unreadable or replacement is required, the DMA 1-1 to DMA 4-1 are simultaneously replaced by the next DMAs (i.e., DMA 1-2, DMA 2-2, DMA 3-2, and DMA 4-2). The four DMAs are simultaneously replaced in order to facilitate the recovery process after a system fault occurs.

The defect management information recorded in the DMA is important information used for enabling the user data to be read or to be written even when a defect occurs in the user area. Accordingly, to increase fault tolerance, the same data is written to a plurality of areas and the DMA itself can be relocated, as described above.

However, if all of the DMAs 1 to 4 become unreadable for some reason, the user data cannot be read out. Therefore, minimum defect management information required for reading the user data is recorded in an area other than the DMA. Thus, the present invention provides a method for allowing the readout of the user data even when the DMA becomes unreadable.

(2) Operation of Information Recording/Playback Apparatus

To record defect management information in an area other than the DMA, such an area (hereinafter referred to as a “backup DMA”) must be reserved. In a first mode, the spare area for user data is used as the backup DMA.

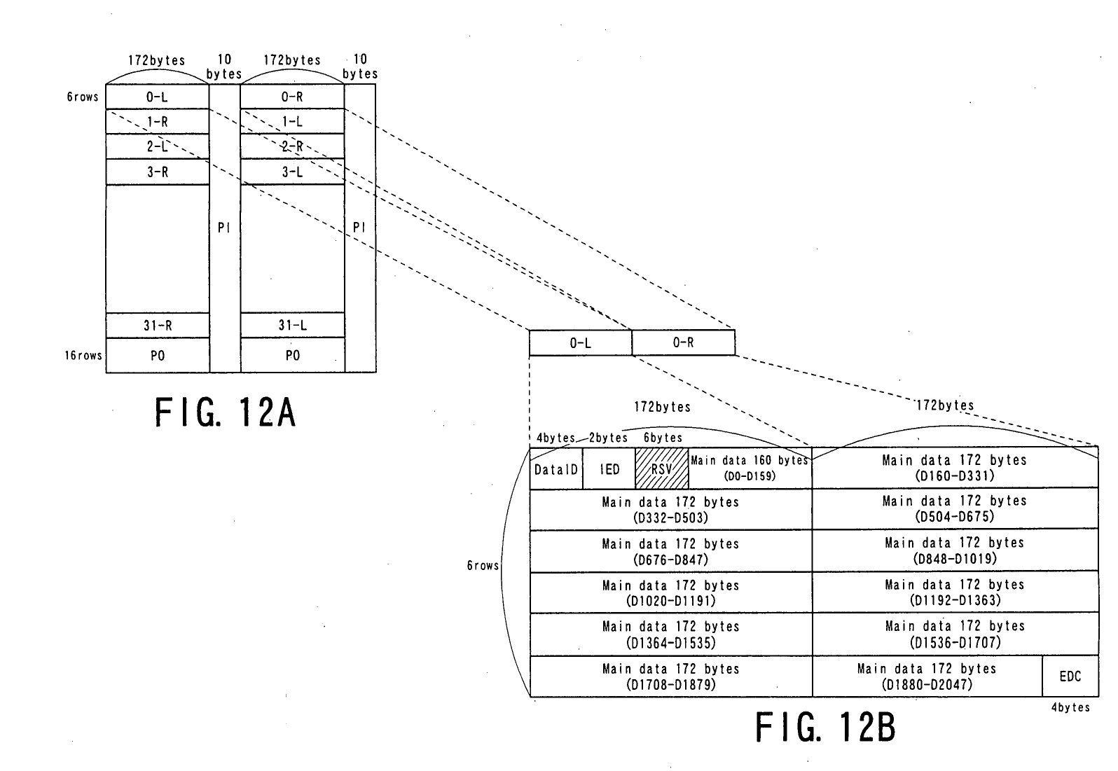

FIGS. 12A and 12B illustrate the data structure of user data recorded on the information storage medium 1 (e.g., an HD DVD-RW).

The user data is recorded on an ECC block basis. The ECC block is divided into units of data known as sectors.

FIG. 12B illustrates the data structure of the sector. The sector contains the following fields from the head to the tail thereof: a 4-byte “Data ID”; a 2-byte “IED (ID error detection)”; a 6-byte reserved area (“RSV”); a 2048-byte (2-Kbyte) field for storing main data starting from D0 to D2047; and a 4-byte EDC (error detection code).

The EDC is used for detecting an error in the 2060-byte data starting from the head to the tail of the main data (up to D2047). However, the EDC does not provide the error correction capability. Even when the error correction is impossible on an ECC block basis, it can be determined whether the data is effective or not (i.e., an error can be detected or not) on a sector basis by using the EDC.

Since the main data area is scrambled, an error must be detected using the EDC after the main data is descrambled.

As shown in FIG. 12B, the sector is divided into 12 rows: 6 rows in the left and 6 rows in the right. One row is 172 bytes.

User data is recorded in the main data area (2 Kbytes from D0 to D2047).

FIG. 12A illustrates the data structure of the ECC block. As noted above, in the HD DVD-RW, the ECC block contains 32 sectors starting from a sector 0 to a sector 31.

In the uppermost block of FIG. 12A, two areas designated as “0-L” and “0-R” are shown. The two areas correspond to the divided data of one sector shown in FIG. 12B: the data in the 6 rows on the left and the data in the 6 rows on the right, respectively. In the second block of FIG. 12A from the top, the data in the sector 1 is divided into six rows on the left and six rows on the right. The data on the left and data on the right are then swapped and are disposed in the areas “1-R” and “1-L”. Similarly, the data on the left and the data on the right are swapped for every second sector up to the sector 31 (areas “31-R” and “31-L”).

Additionally, in the ECC block, parity code is attached to the data in each of the 32 sectors in order to correct an error. The parity code includes a 10-byte PI code (inner parity code) attached to each row having 172 bytes and a 16-row PO code (outer parity code) attached to the set of 192 rows in the longitudinal direction (6 rows×32). The PI code enables the error correction in the row direction while the PO code enables the error correction in the column direction.

The data structure of the ECC block including these parity codes is (172+10)×2 bytes (i.e., 182 bytes×2 columns) in the transverse direction and is (6 rows×32+16 rows) (i.e., 208 rows) in the longitudinal direction.

As shown in FIG. 12B, the sector storing the user data includes a 6-byte reserved area (RSV). Since one ECC block of the HD DVD-RW includes 32 sectors, one ECC block has 192 (32×6)-byte reserved area (“RSV”).

According to the first mode, the defect management information is recorded in this reserved area (“RSV”), which serves as the backup DMA.

To use the backup DMA as a recording area of the defect management information relating to a primary defect, the reserved area (RSV) stores information such as a write start physical address (“location of LSN0”), the entry type (“Entry type”), and the defective physical sector number (“Defective Physical sector number”). This information is then stored in the spare area together with the user data.

Additionally, to use the backup DMA as a recording area of the defect management information relating to a secondary defect, the reserved area (RSV) stores information such as the address to be relocated, the replacement address, and a flag indicating whether the data has been relocated. This information is then stored in the spare area together with the user data.

In a second mode of the backup DMA, a predetermined sub-area in the spare area is allocated to the backup DMA in advance. Although a double area for the original DMA and the backup DMA are needed, the reliability increases. In addition, if the data format of the backup DMA is set to be the same as that of the original DMA, new read and write control is not required, thus reducing the development cost.

Additionally, one of the method of recording the defect management information in only the original DMA and the method of recording the defect management information in the original DMA and the backup DMA may be selected by means of, for example, an external control signal.

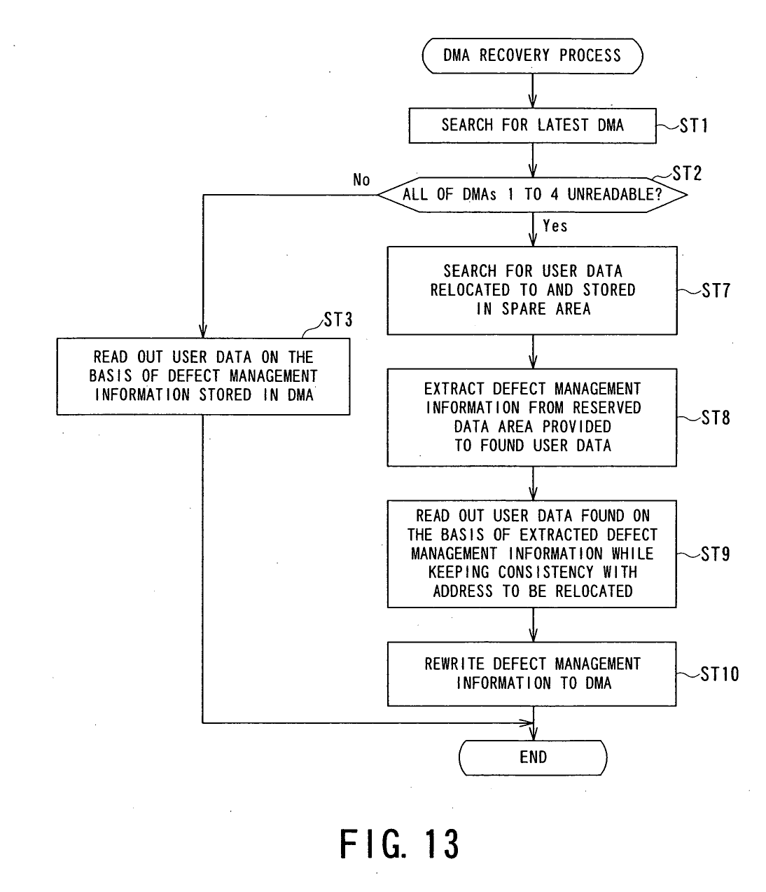

FIG. 13 is a flow chart illustrating the operation of the information recording/playback apparatus 100 when the backup DMA is recorded in the first mode, in particular, the operation of the information recording/playback apparatus 100 when all the DMAs become unreadable.

As in the normal process, the latest DMA is searched for (step ST1). If any one of the four DMAs (the DMAs 1 to 4) is not found or the defect management information in all the four DMAs are unreadable (Yes at step ST2), the process flow proceeds to step ST7.

At step ST7, the user data relocated to and recorded in the spare area is searched for. This search may be sequentially carried out from the starting point of the spare area. Alternatively, the starting address of the user data in the spare area may be recorded in an area at a predetermined address, and that address information may be referenced.

Subsequently, the defect management information recorded in the reserved area (RSV) of the found user data is extracted (step ST8).

The extracted defect management information includes the address to be relocated and the replacement address. By referencing this information, the user data is read out while keeping the consistency with the address to be relocated (step ST9).

There is a possibility that the data cannot be read out from the DMA due to temporary adhesion of dust. Accordingly, the defect management information read out from the backup DMA may be rewritten to the original DMA (step ST10).

Additionally, one of the method of recording the defect management information in only the original DMA and the method of recording the defect management information in the original DMA and the backup DMA may be selected by means of, for example, an external control signal.

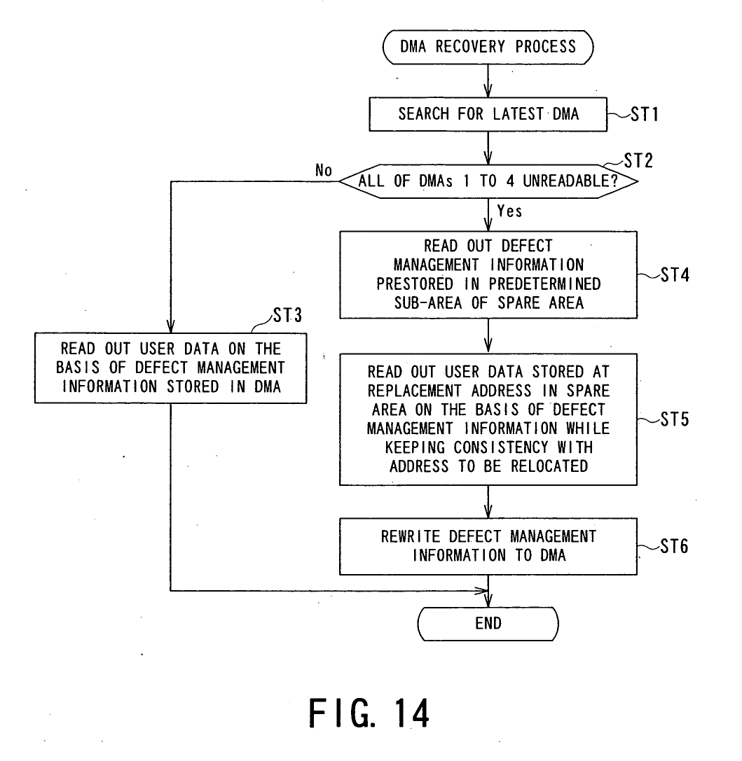

FIG. 14 is a flow chart illustrating the operation of the information recording/playback apparatus 100 when the backup DMA is recorded in the second mode.

The difference between this operation and that in the first mode shown in FIG. 13 primarily lies in step ST4. In the second mode, the backup DMA is recorded in the spare area at a predetermined address, not in the reserved area (RSV) in the user data. Accordingly, at step ST4, the defect management information is read out from the predetermined area (backup DMA) in this spare area. The user data is then read out on the basis of the defect management information.

(3) Configuration of Information Recording/Playback Apparatus

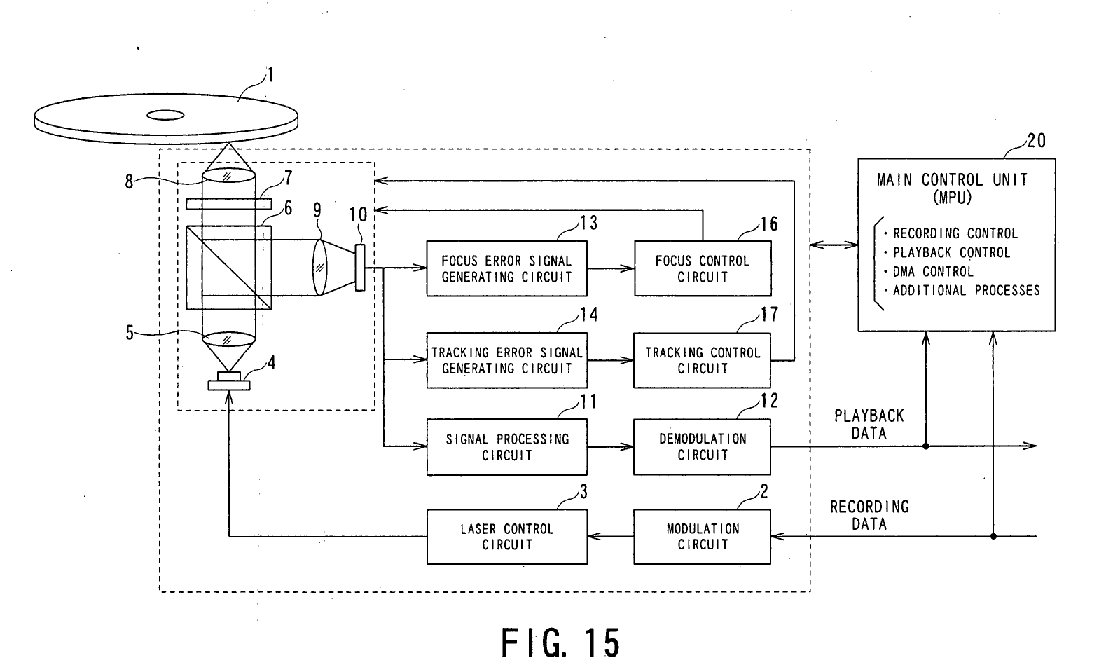

FIG. 15 illustrates the system configuration of the information recording/playback apparatus 100 according to the present embodiment.

The information recording/playback apparatus 100 includes a modulation circuit 2, a laser control circuit 3, a laser 4, a collimator lens 5, a polarized beam splitter (PBS) 6, a quarter wavelength plate 7, an objective lens 8, a condenser lens 9, a light detector 10, a signal processing circuit 11, a demodulation circuit 12, a focus error signal generating circuit 13, a tracking error signal generating circuit 14, a focus control circuit 16, a tracking control circuit 17, and a main control unit 20.

The main control unit 20 controls a drive unit. The drive unit includes the modulation circuit 2, the laser control circuit 3, the laser 4, the collimator lens 5, the PBS 6, the quarter wavelength plate 7, the objective lens 8, the condenser lens 9, the light detector 10, the signal processing circuit 11, the demodulation circuit 12, the focus error signal generating circuit 13, the tracking error signal generating circuit 14, the focus control circuit 16, and the tracking control circuit 17.

The data recording operation performed by the information recording/playback apparatus 100 is described next. The data recording operation is controlled by the main control unit 20. Recording data (data symbol) is modulated into a predetermined series of channel bits by the modulation circuit 2. The series of channel bits corresponding to the recording data is converted to laser driving waveforms by the laser control circuit 3. The laser control circuit 3 drives the laser 4 using control pulses to record data in the form of a desired bit series on the information storage medium 1. The recording light beam emitted from the laser 4 is converted into parallel light beams by the collimator lens 5 and is incident onto the PBS 6. The light beams pass through the PBS 6 and the quarter wavelength plate 7. The light beams are then collected on an information recording surface of the information storage medium 1 by the objective lens 8. Under the focus control of the focus control circuit 16 and the tracking control of the tracking control circuit 17, the collected beam is maintained so that an optimally small spot is obtained on the information recording surface of the information storage medium 1.

The data playback operation performed by the information recording/playback apparatus 100 is described next. The playback operation of data is controlled by the main control unit 20. On the basis of a data playback instruction from the main control unit 20, the laser 4 emits a playback light beam. The playback light beam emitted from the laser 4 is converted to parallel light beams by the collimator lens 5 and is incident onto the PBS 6. The light beams pass through the PBS 6 and the quarter wavelength plate 7. The light beams are then collected on the information recording surface of the information storage medium 1 by the objective lens 8. Under the focus control of the focus control circuit 16 and the tracking control of the tracking control circuit 17, the collected beam is maintained so that an optimal small spot is obtained on the information recording surface of the information storage medium 1. At that time, the playback light beam emitted onto the information storage medium 1 is reflected off the reflecting film or a reflective recording film on the information recording surface. The reflected beam passes through the objective lens 8 in the opposite direction and is converted to parallel beams again. The reflected beams pass through the quarter wavelength plate 7 and have polarized light perpendicular to the incident light. The reflected beams are reflected off the PBS 6. The light beams reflected off the PBS 6 are collected into a converged light beam by the condenser lens 9. The converged light is made incident onto the light detector 10. The light detector 10 includes, for example, a four-section photodetector. The light beam incident on the light detector 10 is photoelectrically converted into an electric signal. The electric signal is amplified. The amplified signal is equalized and binarized into binary data by the signal processing circuit 11. The binary data is delivered to the demodulation circuit 12. The binary data is subjected to a demodulating operation of a predetermined demodulating method in the demodulation circuit 12. Thus, playback data is output.

Additionally, on the basis of part of the electric signal output from the light detector 10, the focus error signal generating circuit 13 generates a focus error signal. In the same manner, on the basis of part of the electric signal output from the light detector 10, the tracking error signal generating circuit 14 generates a tracking error signal. The focus control circuit 16 controls the focus of a beam spot on the basis of the focus error signal. The tracking control circuit 17 controls the tracking of the beam spot on the basis of the tracking error signal.

The replacement operation performed by the main control unit 20 is described next. When formatting the information storage medium 1, certification is executed. At that time, the main control unit 20 detects the presence of any defects of the information storage medium 1. The defect management information relating to the defects detected at that time (i.e., defect management information relating to the initial defects) is recorded in the PDL in the DMA of the information storage medium 1 by the main control unit 20. The defect management information includes the address of a sector to be relocated and the replacement address of the sector. During ordinary recording, the main control unit 20 detects a defect of the information storage medium 1. The defect management information relating to the defect detected at that time (i.e., defect management information relating to the secondary defect) is recorded in the SDL in the DMA of the information storage medium 1 by the main control unit 20. The defect management information includes the address of a first sector of the ECC block to be relocated and the address of a first sector of the replacement ECC block. On the basis of the PDL and SDL, the access to the sector to be relocated can be considered to be the access to the replacement sector.

According to the present embodiment, means for recording data on the information storage medium 1 of the information recording/playback apparatus 100 is included in recording control means of the main control unit 20. Also, means for playing back data from the information storage medium 1 is included in playback control means of the main control unit 20.

Means for writing the defect management information to the backup DMA in addition to the original DMAs and reading the defect management information from the backup DMA when all the original DMAs are unreadable is included in DMA control means of the main control unit 20.

According to the present embodiment, the information recording/playback apparatus 100 can correctly read out the recorded user data even when the defect management information stored in all the DMAs becomes unreadable.

While the invention will be described in conjunction with the preferred embodiments, it will be understood that they are not intended to limit the invention to these embodiments. On the contrary, the invention is intended to be realized by modifying its components within the spirit and scope of the invention as defined by the claims. Additionally, the invention is intended to be realized by combining appropriate components from among a plurality of components disclosed in the preferred embodiments. For example, some of the components may be removed from all the components disclosed in the preferred embodiments. Furthermore, components in a plurality of the preferred embodiments may be appropriately combined.

What is claimed is:

1. A rewritable information storage medium comprising:
a user area for storing user data;
a defect management area for storing defect management information relating to a defective area in the user area; and
a spare area serving as a replacement area for storing the user data that was unable to be stored in the defective area;
wherein the defect management information is stored in an area other than the defect management area in addition to the defect management area.

2. The rewritable information storage medium according to claim 1, wherein the defect management information includes address information indicating the defective area that was unable to store the user data and address information indicating the spare area serving as the replacement area storing the user data.

3. The rewritable information storage medium according to claim 1, wherein the defect management information includes defect address information indicating the defective area that was unable to store the user data.

4. The rewritable information storage medium according to claim 1, wherein the defect management information includes a physical address of a starting point of the user data relocated and stored in the spare area.

5. The rewritable information storage medium according to claim 1, wherein the area other than the defect management area is part of the spare area.

6. The rewritable information storage medium according to claim 1, wherein the area other than the defect management area is a reserved data area provided in the user data relocated and stored in the spare area.

7. The rewritable information storage medium according to claim 1, wherein the defect management area is capable of storing the defect management information read out of the area other than the defect management area.

8. The rewritable information storage medium according to claim 1, wherein it is possible to select whether the area other than the defect management area is capable of storing the defect management information or not.

9. The rewritable information storage medium according to claim 1, wherein it is possible to select whether the user data is capable of being read out or not from the area other than the defect management area on the basis of the defect management information stored therein.

10. An information recording/playback apparatus for recording data on and playing back data from a rewritable information storage medium, comprising:
first storing means for storing user data in a user area of the information storage medium;
second storing means for storing defect management information relating to a defective area of the user area in a defect management area of the information storage medium;
third storing means for relocating and storing user data that was unable to be stored in the defective area in a spare area of the information storage medium; and
fourth storing means for storing the defect management information in an area other than the defect management area in addition to the defect management area.

11. An information recording/playback method for recording data on and playing back data from a rewritable information storage medium, comprising the steps of:
storing user data in a user area of the information storage medium;
storing defect management information relating to a defective area of the user area in a defect management area of the information storage medium;
relocating and storing user data that was unable to be stored in the defective area in a spare area of the information storage medium; and
storing the defect management information in an area other than the defect management area in addition to the defect management area.
